(19) United States
(12) Patent Application Publication
(10) Pub. No.: US 2018/0059291 A1
(43) Pub. Date: Mar. 1, 2018

(54) ANTI-REFLECTIVE AND ANTI-FOGGING MATERIALS

(71) Applicant: AGENCY FOR SCIENCE, TECHNOLOGY AND RESEARCH, Singapore (SG)

(72) Inventors: Xue LI, Singapore (SG); Ren Bin YANG, Singapore (SG); Mohamed Sultan Mohiddin SAIFULLAH, Singapore (SG); Siew Ling Karen CHONG, Singapore (SG); Chang Sheng LEE, Singapore (SG); Yee Chong LOKE, Singapore (SG); Ai Yu HE, Singapore (SG)

(21) Appl. No.: 15/556,291

(22) PCT Filed: Mar. 7, 2016
(86) PCT No.: PCT/SG2016/050106

§ 371 Date: Sep. 6, 2017

(30) Foreign Application Priority Data
Mar. 6, 2015 (SG) 10201501746R

(51) Int. Cl. G02B 1/18; G03F 7/00; G02B 1/118; C23C 16/455

(52) U.S. Cl. CPC G02B 1/18; G03F 7/0002; B29C 2059/023; C23C 16/45525; G02B 1/118

(57) ABSTRACT

The present invention provides a textured polymer substrate comprising nano-sized surface features that are arranged in a single array or in a hierarchical array, and at least one layer of an amorphous, hydrophilic layer deposited thereon. The disclosed textured polymer substrate is advantageously suited for providing anti-reflective, anti-fogging and anti-UV materials.

### CROSS-REFERENCE TO RELATED APPLICATIONS

This application claims the benefit of priority of Singapore patent application No. 10201501746R, filed 6 Mar. 2015, the contents of it being hereby incorporated by reference in its entirety for all purposes.

### TECHNICAL FIELD

The present invention generally relates to materials having anti-reflective, anti-fogging and anti-UV properties, and their applications thereof.

### BACKGROUND ART

Transparent materials, such as glasses, swim goggles, screens, visors and displays, frequently suffer from fogging where a layer of water droplets condenses on the material surface, thus scattering light and significantly reducing the optical transmittance of the material. An increase in the reflection of visible light leads to a decrease in transmittance of light, thereby undermining the purpose of the transparent material.

To overcome the above problem, anti-fog phenomenon on a surface of a material can be achieved by several methods. The surface wettability of the material may be tuned to provide a superhydrophobic surface. On superhydrophobic surfaces, the condensed water tends to form larger droplets which can roll off the surface easily. The surface wettability of the material may alternatively be tuned to provide a superhydrophilic surface where, instead of forming droplets, water will spread to form a thin, even layer on top of the surface which can then be evaporated off easily. Surface wettabilities can be adjusted by modification of a material's surface chemical composition and/or its surface geometric structure.

In another method, anti-reflective structures may be used to reduce the reflection (or glare) of light and increase the transmission of light through a material.

However, there is a need to provide improved materials that offer one or more of the above properties. There is also a need to provide transparent materials that overcome, or at least ameliorate, one or more of the disadvantages described above.

### SUMMARY OF INVENTION

In one aspect of the present invention, there is provided a textured polymer substrate comprising nano-sized surface features which are integrally formed on at least one surface of the polymer substrate, said polymer substrate surface having at least one substantially amorphous oxide layer deposited thereon which conforms to said surface features.

Advantageously, the nano-sized surface features of the disclosed polymer substrate may provide anti-reflective properties to the polymer material. The nano-sized surface features may reduce or substantially prevent scattering of incident light falling on said polymer substrate. The nano-sized surface features may improve the transmittance of electromagnetic (“EM”) radiation through the polymer substrate, for instance, the transmittance of the EM radiation in the visible light spectrum.

Advantageously, the amorphous oxide layer may be selected to provide the disclosed polymer substrate with an anti-fogging property by presenting hydrophilicity or hydrophobicity. The anti-reflective and anti-fogging properties may be expressed additively or synergistically. It has been surprisingly found that amorphous metal oxide, in particular, amorphous (non-crystalline) titanium (II) oxide (TiO₂) may be particularly useful for conferring an anti-fogging property to the disclosed textured polymer substrate. Advantageously, the amorphous titanium oxide layer can be readily deposited without the use of heat-intensive techniques e.g., pulsed laser ablation, sputtering, or thermal chemical vapor deposition (TCVD), which may otherwise deform the polymer substrate. In one embodiment, the amorphous oxide may be advantageously deposited by an Atomic Layer Deposition (ALD) technique, which can be performed at temperatures not exceeding glass transition temperatures of the polymer substrate. Further advantageously, the use of ALD affords precise thickness control of the metal oxide layer, which allows the deposited layer to exhibit a substantially even thickness across coated surfaces. This is important because an uneven coating could destroy the fidelity of the topological features and adversely affect the optical as well as anti-reflective properties of the coated surface features.

Another aspect of the invention relates to a method of preparing a polymer substrate, said method comprising the steps of: imprinting a surface of said polymer substrate with a patterned mold to integrally form a patterned surface having an array of micro-sized structures; embossing said patterned surface to form a hierarchical array, wherein nano-sized surface features are integrally formed on said micro-sized structures; and depositing an amorphous oxide layer over said polymer substrate surface.

Advantageously, the disclosed method provides a means for texturing polymer-based substrates to impart anti-reflective and anti-fogging properties, which may be expressed additively. In particular, the disclosed imprinting step and embossing step may act in cooperation to form hierarchical structures, wherein nano-sized surface features are integrally embossed on a surface of micron-sized structures already imprinted on the polymer substrate surface. Advantageously, the patterned surface may be selectively engineered as one exhibiting biomimetic properties, e.g., moth's eye, lotus leaf, by imprinting corresponding topographical surface features thereon. For instance, molds having hexagonal patterns may be used to provide an ommatidium, or ommatidia-like pattern on the polymer substrate surface.

The disclosed method further provides means for obtaining anti-fogging properties by deposition of an amorphous oxide layer. In embodiments, the amorphous oxide layer may comprise a metal oxide (e.g., TiO₂) or composites of metal oxides, metal-Si oxides to thereby confer superhydrophilicity or superhydrophobicity to the coated polymer substrate. Advantageously, as will be further described herein, this deposition step can be undertaken at mild temperatures without deforming the polymer substrate and/or damaging the hierarchical structures formed thereon.

### Definitions

The following words and terms used herein shall have the meaning indicated:

The word “substantially” does not exclude “completely” e.g. a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Certain embodiments may also be described broadly and generically herein. Each of the narrower species and subgeneric groupings falling within the generic disclosure also form part of the disclosure. This includes the generic description of the embodiments with a proviso or negative limitation removing any subject matter from the genus, regardless of whether or not the excised material is specifically recited herein.

### DETAILED DISCLOSURE OF EMBODIMENTS

Exemplary, non-limiting embodiments of a textured polymer substrate according to the present disclosure shall now be disclosed.

The nano-sized surface features may be formed in a one-dimensional array or a single array. By “single array”, the term may refer to an arrangement of non-hierarchical surface features wherein the nano-sized surface features are not provided on a surface of topological features that have been earlier imprinted on the polymer substrate, but are instead disposed directly on the surface of the polymer substrate. When provided in a single or one-dimensional array, the nano-sized surface features may be substantially homogeneous in their distribution and size. In one embodiment, the disclosed polymer substrate may comprise a single array of nano-sized surface features, each nano-sized surface feature having a width dimension that is lesser than or equal to the wavelength of visible violet radiation, i.e., lesser than 400 nm, lesser than 390 nm or lesser than 380 nm. Advantageously, a textured polymer substrate comprising a single array of nano-sized surface features may exhibit low or no reflectivity, e.g., characterized by a transmittance in the visible light spectrum of from about 60% to 100%, from about 60%-90%, from about 60%-80%, from about 60%-70%, from about 70%-80%, from about 70%-90%, from about 80%-100%, from about 80%-90%, from about 90%-100%, or from about 95-100%. Transmittance may be measured by the methods disclosed herein.

The nano-sized surface features may be formed on a hierarchical array. For instance, the polymer substrate surface may comprise an array of micro-sized structures that are integrally formed on said polymer substrate, each micro-sized feature in turn being elaborated or imprinted with nano-sized surface features on its surface thereon.

For instance, hierarchical structures may refer to topological structures that are imprinted sequentially, usually in increasingly smaller dimensions. In the context of the present invention, a hierarchical structure may refer to the embossing of nano-sized features on the surface of existing micro-sized structures formed by an earlier imprinting step. The micro-sized structures may be integrally formed on the polymer substrate. Each micro-sized feature may comprise a planar surface that extends from the surface of the polymer substrate. Such planar surfaces may refer to a distal end of a cone, a cylinder, or a polygonal (e.g., square, hexagonal) structure extending from the base of the polymer substrate. The nano-sized features may be imprinted or embossed on such a planar surface to thereby form hierarchical structures. Advantageously, it is been demonstrated herein that the provision of hierarchical structures may provide low reflectivity concurrently with UV-resistance, e.g., by selectively causing low transmittance (high reflectivity) of electromagnetic radiation in the UV-A (wavelength: 320-400 nm) and/or UV-B spectrum (wavelength: 290-320 nm). In embodiments disclosed herein, the textured polymer substrate may express, independently, UV-A and/or UV-B transmittance of from 0-60%, 0-10%, 0-20%, 0-30%, 0-40%, 0-50%, 10-60%, 10-50%, 10-40%, 10-30%, 10-20%, 20-60%, 20-50%, 20-40%, 20-30%, 30-60%, 30-50%, 30-40%, 40-60%, 40-50%, or from 50%-60%.

The micro-sized surface features may be geometrically selected to be biomimetic. For instance, the molds used for the imprinting step may be patterned to provide biomimetic surface features on the imprinted polymer substrate. The micro-sized surface features may be provided in a single array. The micro-sized features may comprise tessellated structures. The tessellated structures may be composed of regular, congruently-sized polygons. Suitable polygons may be selected from the group consisting of: trigonal, tetragonal, square, rhombic, pentagonal, hexagonal, heptagonal, octagonal, nonagonal, decagonal, undecagonal, dodecagonal, tridecagonal, tetreadecagonal structures and combinations thereof. In one embodiment, the array of micro-sized structures comprises ommatidium or ommatidia-like structures. Ommatidium or ommatidia-like structures may be biomimetic of moth-eyes and which may be generally depicted by tessellated hexagonal structures.

The micro-sized structures may have a diameter dimension of between about 1 to about 15 microns. In embodiments, the micro-sized structures may have a diameter dimension selected from a range of about 1 to 15 μm, 2 to 15 μm, 3 to 15 μm, 4 to 15 μm, 5 to 15 μm, 6 to 15 μm, 7 to 15 μm, 8 to 15 μm, 9 to 15 μm, 10 to 15 μm, 11 to 15 μm, 12 to 15 μm, 1 to 14 μm, 2 to 14 μm, 3 to 14 μm, 4 to 14 μm, 5 to 14 μm, 6 to 14 μm, 7 to 14 μm, 8 to 14 μm, 9 to 14 μm, 10 to 14 μm, 11 to 14 μm, 12 to 14 μm, 1 to 10 μm, 2 to 10 μm, 3 to 10 μm, 4 to 10 μm, 5 to 10 μm, 6 to 10 μm, 7 to 10 μm, 8 to 10 μm, 9 to 10 μm, 10 to 12 μm, 10 to 13 μm, 10 to 14 μm, and 10 to 15 μm. In embodiments disclosed herein, the micro-sized structures are configured to have a diameter dimension of from about 2 to about 10 μm.

The micro-sized structures may also exhibit a polygonal side dimension of between about 1 to about 6 microns. In embodiments, the micro-sized structures may have a side dimension selected from a range of about 1 to 6 μm, 2 to 6 μm, 3 to 6 μm, 4 to 6 μm, 5 to 6 μm, 1 to 5 μm, 2 to 5 μm, 3 to 5 μm, 4 to 5 μm, 1 to 4 μm, 2 to 4 μm, 3 to 4 μm, 1 to 3 μm, or 2 to 3 μm. In the case of ommatidium or ommatidia-like structures, each hexagonal length (or edge) may be from about 3-5 μm, e.g., 3.25 μm, 3.5 μm, 3.75 μm, 4.0 μm, 4.25 μm, 4.5 μm, 4.75 μm, 5.0 μm.

The nano-sized surface features may be elongate structures having at least one tapered distal end. The elongate structures may also be substantially uniform in cross-section throughout its entire height dimension but comprises a rounded or pointed terminus (e.g., needle). These nano-structures may extend from the polymer substrate surface (single array) or a surface presented by a distal end of the micro-sized structures (hierarchical structures). The nano-structures may assume various geometrical shapes, which may be selected to confer anti-reflective properties, anti-UV properties and/or other biomimetic properties. The nano-structures may be provided in the shapes of nano-cones, nano-pyramids, nano-cylinders, nano-needles, nano-blades and combinations thereof. Each nano-structure may possess at least one height dimension and at least one width dimension. For nano-cones, the width dimension may refer to its diameter at its broadest cross-section (base). For nano-pyramids, the width dimension may refer to the displacement from one vertex to another at the pyramid's base. For nano-cylinders or needles, the width dimension may refer to its diameter occurring substantially throughout the entire length of the cylinder.

The height dimension, or width dimension, or both, of the nano-sized surface features may be lesser than a wavelength of the visible spectrum of electromagnetic radiation (390 nm to 700 nm). In embodiments, both height and width dimensions of the nano-sized surface features may be same or less than the wavelength of visible violet light (380 nm-450 nm). Advantageously, this allows the visible electromagnetic waves pass through these nano-sized surface structures without, or with markedly reduced, reflection or light scattering. The height or width dimension may be independently less than 400 nm, less than 390 nm or less than 380 nm in size

The nano-sized surface features may be characterized by having a width that is between about 50-350 nm. The width dimension may be in a length selected from 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm or may be provided in a range having an upper limit and a lower limit selected from two values defined herein.

The nano-sized surface features may be characterized by having a height dimension that is between about 50-250 nm. The height dimension may be in a length selected from 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm or may be provided in a range having an upper limit and a lower limit selected from two values defined herein. Suitable height and/or width dimensions may also be selected to specifically filter/reflect particular wavelengths in the visible spectrum (e.g., removing the blue/violet spectrum by providing surface features with dimensions exceeding the blue/violet wavelength).

The aspect ratio (a ratio of width:height) may be selected to be from 5:1 to about 1:2. The aspect ratio of the nano-structures may be selected from 5:1, 4:1, 3:1, 2:1, 1:1, or 1:2. In one embodiment, the aspect ratio is 1:1, which advantageously provides sturdier or physically more resilient nano-structures which may be less susceptible to structural deformation or damage (e.g. breakage of tips).

The amorphous oxide layer may comprise an oxide of a metal selected from titanium, zinc, aluminium, cobalt or composites thereof. In one embodiment, the metal oxide layer may comprise a composite oxide e.g., a titanium-silicon oxide composition (TiO₂—SiO₂), zinc-cobalt composite (ZnO/Co₃O₄). In one embodiment, the amorphous oxide layer is a TiO₂ layer. Advantageously, the TiO₂ layer provides ultra-hydrophilicity to the oxide-coated polymer substrate, thereby providing an anti-fogging effect. Further advantageously, the TiO₂ particles may provide anti-UV effects when coated on a single array and may synergistically or additively enhance the anti-UV effects when coated on a hierarchical structure.

The amorphous metal oxide layer may have a substantially uniform thickness, e.g., between 1 to 50 nm thick. In embodiments, the amorphous oxide layer may have a thickness selected from 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49 or 50 nm. In embodiments, the thickness is selected to be from 10 to 50 nm. Particularly, the thickness of the oxide layer may be adjusted such that the width dimension of the coated nano-sized surface features does not exceed the wavelength of radiation intended for transmission.

The metal oxide layer may be substantially evenly distributed across the entire or part of the surface of the polymer substrate. Where the metal oxide is to be deposited onto the micro-sized structures or the nano-sized surface features, the metal oxide layer is substantially conformed to the geometry of these structures, wherein the oxide layer substantially traces the perimeter or the topological definition of the nano- and micro-structures. Advantageously, the evenly distributed metal oxide layer maintains the topological fidelity and integrity of the textured polymer substrate. It is important to maintain the fidelity of the topological features in order to ensure that the favourably optical characteristics of the polymer substrate are not adversely affected or any adverse effects are ameliorated or substantially minimized.

Advantageously, it has been surprisingly found that the metal oxide layer may be substantially amorphous (non-crystalline) without sacrificing its anti-fogging properties. Advantageously, the amorphous metal oxide layer may be deposited by a chemical vapor deposition process, which may be undertaken at conditions that would not deform the polymer substrate or adversely affect the fidelity of the topological features imprinted thereon. In embodiments, the CVD process may be performed at a temperature lower than the glass transition temperature of the polymer substrate. The amorphous metal oxide layer may be deposited by an Atomic Layer Deposition (ALD) process. Advantageously, the ALD process affords precise control over the thickness and uniformity of the topological features. The ALD can be performed at considerably mild temperatures of around 15° C. to 100° C., 20° C. to 100° C., 25° C. to 100° C., 30° C. to 100° C., 40° C. to 100° C., 50° C. to 100° C., 60 to 100° C., 15° C. to 90° C., 20° C. to 90° C., 25° C. to 90° C., 30° C. to 90° C., 40° C. to 90° C., 50° C. to 90° C., 60° C. to 90° C., 15° C. to 80° C., 20° C. to 80° C., 25° C. to 80° C., 30° C. to 80° C., 40° C. to 80° C., 50° C. to 80° C., 60° C. to 80° C., 15° C. to 70° C., 20° C. to 70° C., 25° C. to 70° C., 30° C. to 70° C., 40° C. to 70° C., 50° C. to 70° C., 60° C. to 70° C., 70° C. to 100° C., 70° C. to 90° C., or around 70° C. to 80° C. In another embodiment, the ALD can be performed at ambient or room temperature. Advantageously, the substrate may be composed of polymers such as polycarbonates (“PC”), polyethylene terephthalate (“PET”), poly(methyl methacrylate) (“PMMA”) or copolymers or polymer blends thereof. The substrate may be advantageously composed of a substantially optically transparent polymer, e.g., polycarbonate.

Exemplary, non-limiting embodiments of methods for preparing a textured polymer substrate according to the present disclosure shall now be disclosed.

In one embodiment, there is provided a method of preparing a polymer substrate, the method comprising the steps of: imprinting a surface of said polymer substrate with a patterned mold to integrally form a patterned surface having an array of micro-sized structures; embossing said patterned surface to form a hierarchical array, wherein nano-sized surface features are integrally formed on said micro-sized structures; and depositing an amorphous oxide layer over said polymer substrate surface. In another embodiment, there is provided a method of preparing a polymer substrate, the method comprising the steps of: embossing a surface of said polymer substrate to integrally form a patterned surface having an array of nano-sized surface features on said surface of the polymer substrate; and depositing an amorphous oxide layer over said polymer substrate surface. The disclosed method may comprise a single imprinting step to impart integrally formed nano-sized surface features on a substrate surface in a single array, and depositing an amorphous oxide layer thereon.

The depositing step may comprise atomic layer deposition. In the case of titanium oxide, the use of ALD is particularly advantageous because the deposition of the amorphous metal oxide can be performed at temperatures of around 80° C.-100° C., whereas crystalline growth can typically only be obtained at around 200° C. or more.

Atomic layer deposition may comprise contacting the polymer substrate surface with precursors of the oxide. The oxide may be the oxide of a metal selected from titanium, zinc, aluminium, cobalt or composites thereof. The precursors of titanium oxide may include organic or inorganic titanium salts. In an embodiment, the precursors of titanium oxide may be TiCl₄ and H₂O. The precursors of zinc oxide may include organic or inorganic zinc salts. In an embodiment, the precursors of zinc oxide may be diethyl zinc and H₂O. The precursors of aluminium oxide may include organic or inorganic aluminium salts. In an embodiment, the precursors of aluminium oxide may be trimethylaluminium and H₂O. The oxide may be the oxide of a metalloid such as silicon. The precursors of silicon oxide may include organic or inorganic silicon precursors. In an embodiment, the precursors of silicon oxide may be tris(tert-pentoxy)silanol and trimethylaluminium. It should be noted that the deposition conditions may be dependent on the actual ALD system used and one may adjust the conditions reaction/purge conditions as necessary to obtain the required coating or thickness.

The imprinting step may be performed at a temperature above the glass transition temperature of said polymer substrate. When the polymer substrate is PC, the imprinting step may be performed at a temperature of around 180° C.

The embossing step may be performed at a temperature lower than the glass transition temperature of said polymer substrate. When the polymer substrate is PC, the embossing step may be performed at a temperature of around 150° C.

Both imprinting and embossing steps may be independently carried out at pressures of from about 30 to 70 bars, 30 to 60 bars, 30 to 50 bars, 30 to 40 bars, 40 to 70 bars, 40 to 60 bars, 40 to 50 bars, 50 to 70 bars, or 50 to 60 bars. In one embodiment, both imprinting and embossing steps are carried out a pressure of 50 bars and at a temperature as disclosed above. Advantageously, the disclosed steps allow the secondary imprinting or embossing of the nano-sized surface features without substantially deforming the topology of the micro-structures formed by the first imprinting step.

In embodiments, the mold of the imprinting step may be selected or suitably patterned to provide tessellated polygonal structures on the polymer surface. The polygonal structures may be micro-sized structures such as those defined hereinabove.

The embossing step may comprise contacting the patterned surface having micro-structures imprinted thereon with a second mold to integrally form nano-sized surface features on at least a surface of the micro-structures, thereby resulting in the formation of hierarchical arrays.

The nano-sized surface features may comprise structures selected from the group consisting of: nano-cones, nano-pyramids, nano-cylinders, nano-needles, nano-blades, and combinations thereof. The nano-sized surface features may be selected from shapes disclosed herein above.

The disclosed method may comprise an additional cleaning or etching step of to improve the resolution or to refine the topological features of the micro- and/or nano-structures. The etching step may comprise subjecting the embossed polymer substrate to plasma treatment, e.g., argon plasma treatment. The plasma cleaning step may be performed prior to the ALD to provide improved adhesion of the coating onto the polymer substrate.

The amorphous oxide layer may be a titanium oxide layer, an aluminum oxide layer, a zinc oxide layer or a silicon dioxide layer. The oxide layer may comprise a composite formed from a combination of the oxides disclosed herein. In one embodiment, the oxide layer is a titanium oxide thin film. The deposition step may be undertaken to obtain a thickness of said metal oxide layer of from about 10 to 50 nm.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIG. 1 is a schematic diagram illustrating a process to prepare a textured polymer substrate in accordance with an embodiment of the present disclosure.

FIG. 2 is a schematic diagram illustrating a process to conduct the depositing step of the method in accordance with an embodiment of the present disclosure.

FIG. 3 shows scanning electron microscopic (SEM) images of (a) a top view of the imprinted film in two magnifications and (b) a 45° tilted view of the imprinted film, wherein the imprinted film was produced in Example 1, with Example 1b using an unpatterned polycarbonate film.

FIG. 4 shows scanning electron microscopic (SEM) images of (a) a top view of the imprinted film and (b) a 45° tilted view of the imprinted film, wherein the imprinted film was produced from all steps of Example 1.

FIG. 5 shows scanning electron microscopic (SEM) images of (a) a top view of the imprinted film in two magnifications and (b) a 45° tilted view of the imprinted film in two magnifications, wherein the imprinted film was produced from Examples 1b and 1c, wherein an unpatterned polycarbonate film was used in Example 1b. The SEM images show metal oxide being conformally deposited on the anti-reflective structures via ALD.

FIG. 6 shows a graph of transmittance measurements performed on the imprinted films produced from Example 1.

### EXAMPLES

Non-limiting examples of the invention will be further described in greater detail by reference to specific Examples, which should not be construed as in any way limiting the scope of the invention.

### Example 1

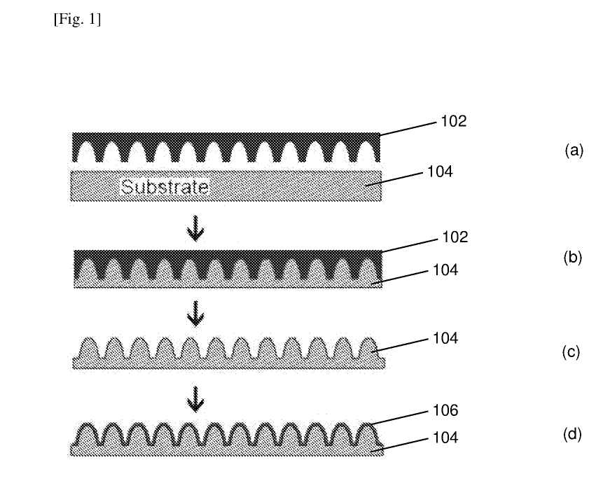

A schematic diagram illustrating a process to prepare a textured polymer substrate in accordance with an embodiment of the present disclosure is shown in FIG. 1.

In step (a) of FIG. 1, 102 is used as a mold to imprint a surface of a substrate 104. Mold 102 has nano-sized surface features complementary to the nano-sized surface features desired to be formed onto the surface of substrate 104. The nano-sized surface features may be of a size smaller than the wavelength of light, thereby creating a graded refractive index to increase the transmission of light. The surface of substrate 104 may be a plain, unpatterned surface of substrate 104 or the surface of micro-sized features integrally formed on substrate 104. Where the surface of substrate 104 is a surface of micro-sized features integrally formed on substrate 104, an optional step prior to step (a) comprises forming micro-sized features on substrate 104. Step (b) is performed at conditions to create imprints on the surface of substrate 104 complementary to the mold 102. Step (c) is performed at conditions to enable removal of the mold 102 and result in imprinted substrate 104. In step (d), a layer 106 is deposited on the surface of the imprinted substrate 104. Layer 106 conforms to the imprints on substrate 104. Layer 106 may confer superhydrophilic properties on substrate 104 to result in an anti-fogging substrate. Layer 106 may further confer anti-UV properties on the substrate.

The examples below follow the process illustrated in FIG. 1.

### Example 1a

In Example 1a, the optional step prior to step (a) is demonstrated by using a nanoimprint lithography technique. Nanoimprint lithography is a simple, low cost, high throughput and high resolution surface patterning technique. An advantage of nanoimprint lithography is that the resolution of the resulting nanoimprints can be as small as 5 nm.

A nickel metal mold with specific micro-sized features was pressed onto a polycarbonate (PC) film of 250 μm in thickness and an area of 2 cm×2 cm. Polycarbonate substrates are commonly used as plastic material for equipment such as goggles, eyewear and visors.

The micro-sized features of the mold were complementary to the micro-sized surface features desired to be formed onto the substrate. The micro-sized surface features desired on the substrate may be geometrically selected to be biomimetic, such as ommatidia-like structures. In this example, the micro-sized surface features desired on the substrate were hexagonally arrayed lens structures of 2-10 μm in diameter.

The micro-sized features were imprinted on the PC film above the glass transition temperature of polycarbonate to create an array of micro-sized surface features integrally formed on the PC film. Specifically, the imprinting was conducted at about 180° C. and 50 bars.

Thereafter, the imprinted film was cooled down to room temperature for demolding.

### Example 1b

In Example 1b, steps (a), (b) and (c) of FIG. 1 are demonstrated, also by using nanoimprint lithography.

A nickel metal mold with specific nanostructures was pressed onto a surface of a polycarbonate (PC) film of 250 μm in thickness and an area of 2 cm×2 cm to imprint the PC film. The nano-sized features of the mold were complementary to the nano-sized surface features desired to be formed onto the surface of the substrate. The nano-sized surface features desired on the substrate may be nano-cones.

The temperature for the imprinting step was chosen to be a temperature below the glass transition temperature of polycarbonate to enable the formation of nano-sized surface features integrally on the micro-sized features of the imprinted film of Example 1a. Specifically, the imprinting was conducted at 150° C. and 50 bars.

Thereafter, the imprinted film was cooled down to 50° C. and the pressure was released. The imprinted film was then cooled down to room temperature before demolding. The imprinted substrate was subsequently plasma treated with argon plasma at 50 W for 1 minute to improve adhesion of oxide to be deposited by ALD on the surface.

The example was repeated this time with an unpatterned polycarbonate film. The temperature for the imprinting step was also 150° C. and 50 bars.

This example evidences that nanoimprinting can provide a convenient method to fabricate both single and hierarchical arrays.

### Example 1c

In Example 1c, step (d) of FIG. 1 is demonstrated by using atomic layer deposition (ALD).

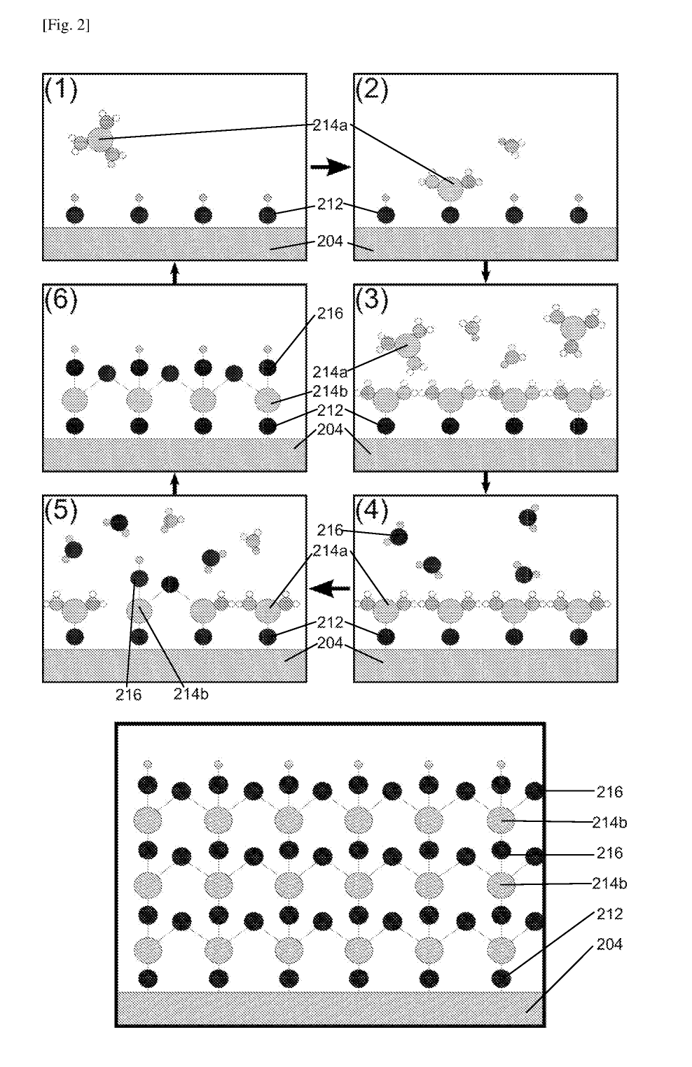

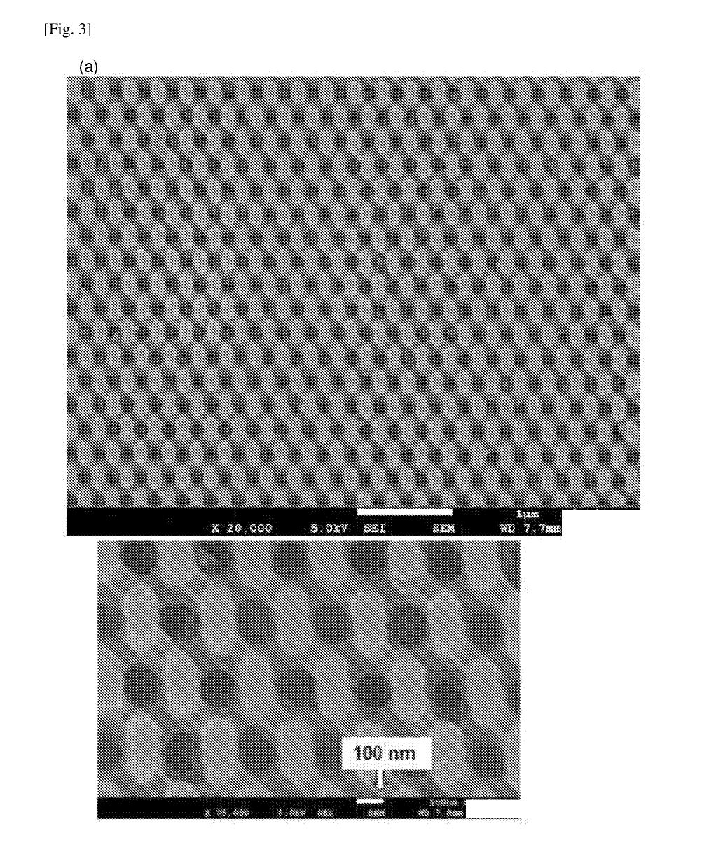

ALD is a vapour phase deposition technique where two or more chemical precursors are introduced into a chamber in a sequential and cyclical manner to react in a self-limiting way on the surface of a substrate to obtain a desired type of film. This method has a distinctive advantage of being able to coat large and complex substrates with very conformal and pin-hole free films. A schematic diagram illustrating a process to conduct the depositing step of the method in accordance with an embodiment of the present disclosure is shown in FIG. 2.

In step (1) of FIG. 2, substrate 204 comprises reaction sites 212 on its surface. First precursor 214a is introduced into the ALD chamber, optionally together with a carrier gas. Substrate 204 is exposed to precursor 214a for a period of time. In step (2), the first precursor 214a reacts with reaction sites 212 to create a half-layer on the substrate surface. The half-layer exposes new surface sites (not shown). In step (3), excess precursor 214a will have no more available reaction sites 212 to react with and are then purged from the ALD chamber. Accordingly, the ALD reaction can be considered a self-limiting reaction. The duration of the purge may be conducted for a certain period of time, or until substantially all excess precursor is purged. In step (4), second precursor 216 is introduced into the ALD chamber, optionally together with a carrier gas. The new surface sites of the half-layer of substrate 204 are exposed to second precursor 216 for a period of time. In step (5), upon reaction of the second precursor 216 with the new surface sites of the first precursor 214a, the final product is formed comprising 214b and 216. The final product is the amorphous hydrophilic metal oxide layer as disclosed herein. Excess second precursor 216 is purged from the ALD chamber. The duration of the purge may be conducted for a certain period of time, or until substantially all excess precursor is purged. In step (6), a full layer, or a complete monolayer, of final product is formed on the surface of substrate 204. This first monolayer may create reaction sites 212 again and steps (1) to (6) may be repeated to generate further monolayers if desired.

Example 1c therefore follows the process illustrated in FIG. 2.

The imprinted films from Example 1b were fixed onto a 6 inch wafer and Kapton tape was applied around the edges of these samples to prevent deposition on the underside of the samples. The wafer was placed in a chamber. A nitrogen gas carrier was used and its flow rate was set to 30 standard cm³/min. TiO₂ was deposited onto the imprinted films using the precursors TiCl₄ and H₂O. The ALD process was conducted at a substrate temperature of 80° C. to produce a textured polymer substrate wherein the surface of the polymer substrate has a hydrophilic metal oxide layer deposited thereon to thereby conform to the surface features. The TiO₂ coating produced had a thickness of about 20 nm.

### Example 2

In Example 2, analysis of the textured polymer substrates prepared in Example 1 is conducted.

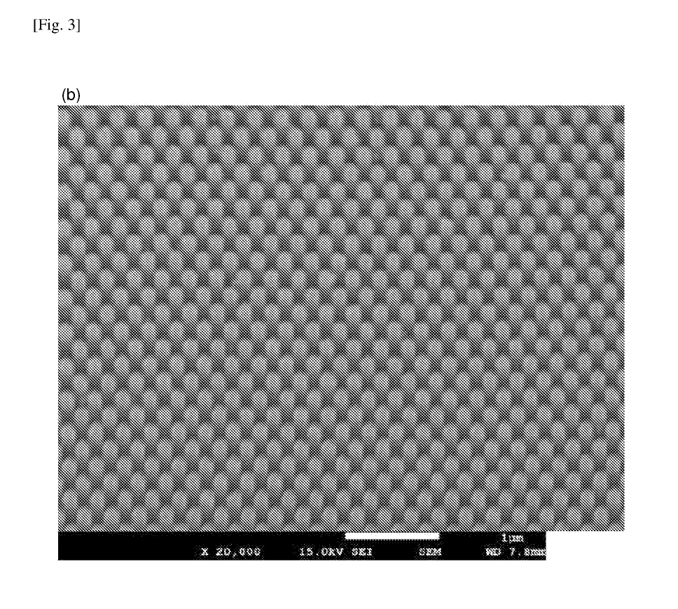

Scanning electron microscopic (SEM) images of the imprinted film produced where Example 1b used an unpatterned polycarbonate film, i.e. where the optional step prior to step (a) of FIG. 1 is not conducted, are shown in FIG. 3. Particularly, FIG. 3a shows a top view of the imprinted substrate in two magnifications, while FIG. 3b shows a 45° tilted view of the imprinted substrate. The SEM images of FIG. 3 shows 100% yields for the imprinted film comprising nano-sized surface features formed on a single array.

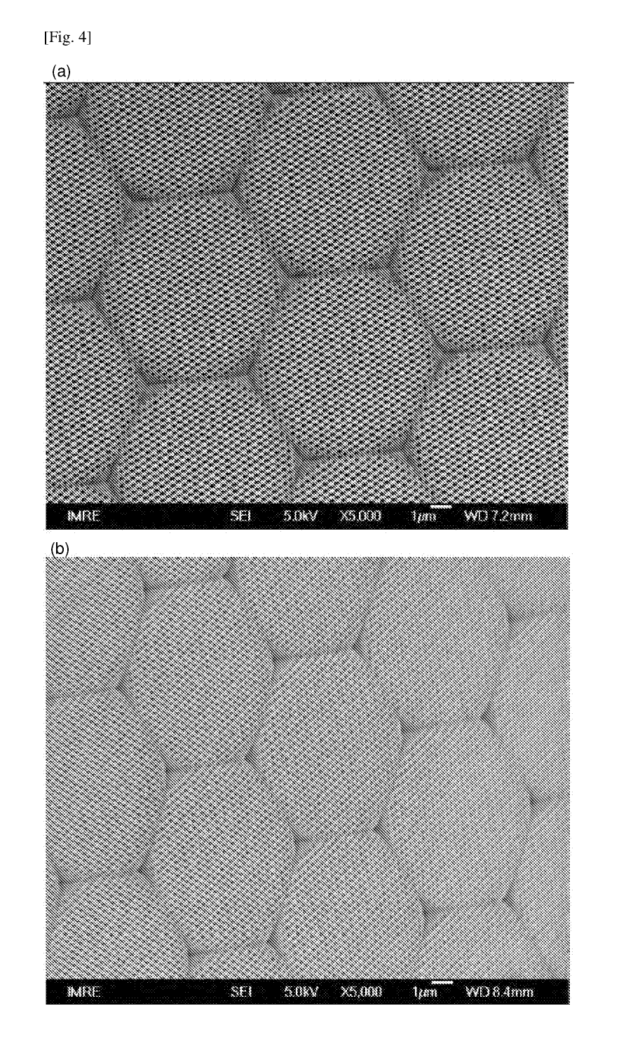

SEM images of the imprinted film produced from all steps of Example 1 are shown in FIG. 4. Particularly, FIG. 4a shows a top view of the imprinted substrate, while FIG. 4b shows a 45° tilted view of the imprinted substrate. The imprinted film produced comprises nano-cones formed on a hierarchical array of micro-sized hexagonal lens structures.

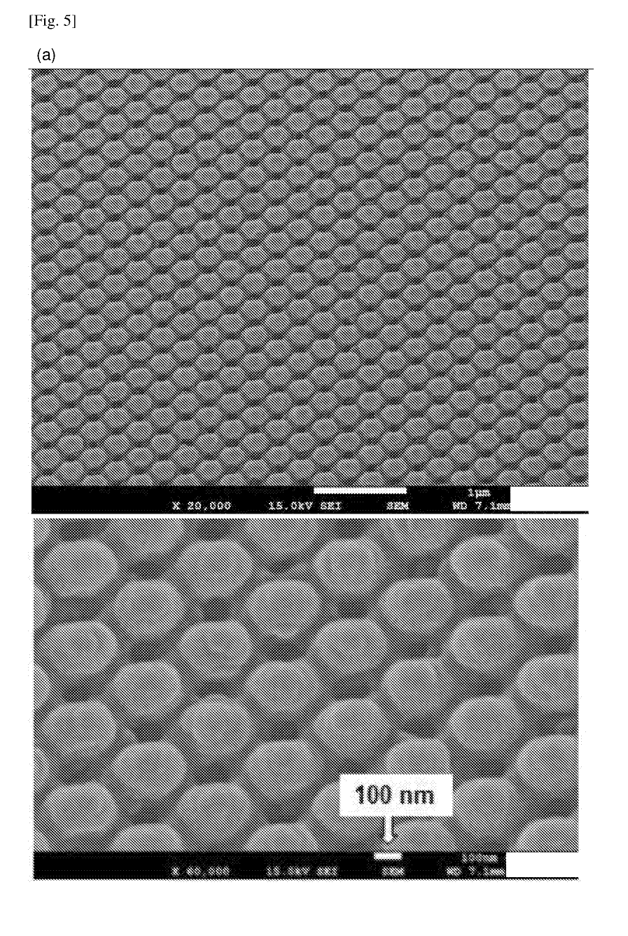

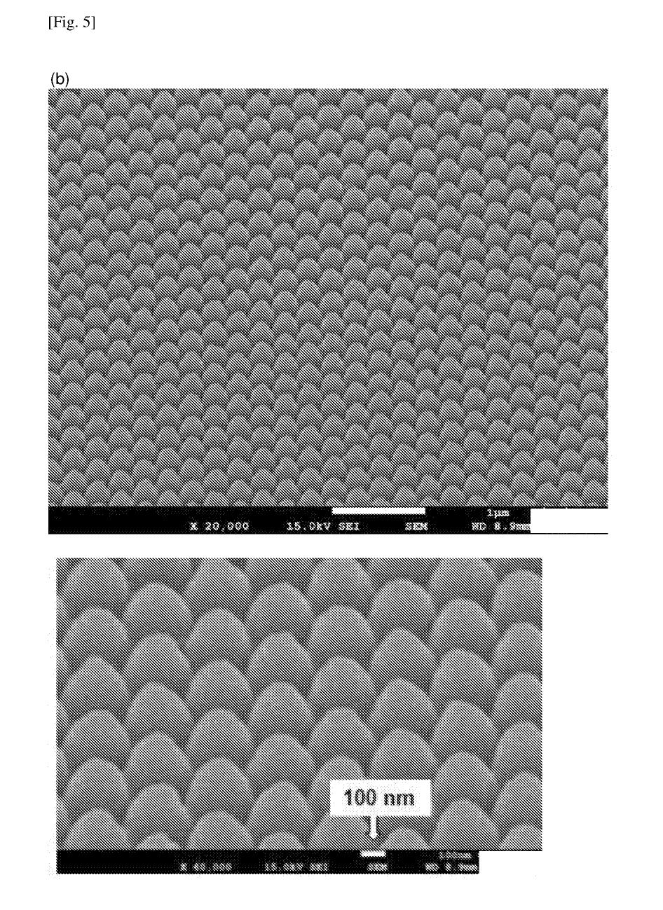

SEM images of the imprinted film produced in Examples 1b and 1c, wherein an unpatterned polycarbonate film was used in Example 1b, are shown in FIG. 5, wherein the images show a layer of oxide deposited on the imprinted film via ALD. Particularly, FIG. 5a shows a top view of the imprinted substrate in two magnifications, while FIG. 5b shows a 45° tilted view of the imprinted substrate in two magnifications.

### Example 3

In Example 3, different precursors for the layer of hydrophilic metal oxide as disclosed herein are analysed.

A total of four different metal oxides were used in this example to deposit onto imprinted samples produced from Example 1: ZnO, TiO₂, SiO₂ and Al₂O₃. The process outlined in Example 1c was followed here.

The precursors, pulse duration, exposure duration and purge duration used in this example are given below.

For ZnO, the precursors used were diethyl zinc (DEZ) and H₂O. The ALD conditions used for DEZ were as follows: pulse/exposure/purge (all in seconds)=0.2/3/30. The ALD conditions used for H₂O were as follows: pulse/exposure/purge (all in seconds)=0.1/3/50.

For TiO₂, the precursors used were TiCl₄ and H₂O. The ALD conditions used for TiCl₄ were as follows: pulse/exposure/purge (all in seconds)=0.1/3/30. The ALD conditions used for H₂O were as follows: pulse/exposure/purge (all in seconds)=0.1/3/50.

For SiO₂, the precursors used were tris(tert-pentoxy)silanol (TPS) and trimethylaluminium (TMA). The ALD conditions used for TPS were as follows: pulse/exposure/purge (all in seconds)=(25/3/3) for three times and 25/3/25 on the fourth time. The ALD conditions used for TMA were as follows: pulse/exposure/purge (all in seconds)=0.2/5/25.

For Al₂O₃, the precursors used were trimethylaluminium (TMA) and H₂O. The ALD conditions used for TMA were as follows: pulse/exposure/purge (all in seconds)=0.1/3/30. The ALD conditions used for H₂O were as follows: pulse/exposure/purge (all in seconds)=0.1/3/50.

The textured polymer substrates comprising the above four metal oxide layers deposited conformally on the surface features by ALD were then analysed for fogging.

Accelerated anti-fog tests were carried out with a water vapour generator (the uMist baby ultrasonic mist generator from Osim, Singapore). The tests were carried out at room temperature conditions (25° C.) for 40 seconds and 3 minutes. The results of the wettability and anti-fog properties of the ALD coated imprinted substrates are shown in Table 1 as follows.

TABLE 1

| | | Fog-test results (after 40 |
|---|---|---|
| | | seconds of continuous |
| Type of coating | Wettability | exposure to water vapour) |
| Al₂O₃ | Superhydrophilic | Slightly fogging |
| SiO₂ | Hydrophobic | Fogging |
| TiO₂ | Superhydrophilic | Clear |
| ZnO | Hydrophilic | Fogging |

Among the four coatings, it is evidenced that TiO₂ showed the best anti-fog property.

Anti-fog tests described above were also carried out for 3 minutes on an imprinted polycarbonate film comprising nano-sized surface features formed on a single array with TiO₂ deposited thereon. Fogging was only observed after 3 minutes.

An anti-fog test described above was also carried out for 1 hour on the single array polycarbonate film with TiO₂ deposited thereon. No fogging was seen in this test. Accordingly, while fogging may appear after a short time, the fog ultimately cleared up thereafter.

### Example 4

In Example 4, transmittance measurements were performed on the imprinted films produced from Example 1.

The imprinted film produced in Example 1b using an unpatterned polycarbonate film showed an improvement in transmission of up to 94% light transmittance in the visible zone as compared to a plain non-imprinted polycarbonate sample which had a light transmittance of up to about 88%.

The imprinted film produced in Example 1b using the hexagonally-patterned film of Example 1a showed a significant drop in the UV-A and UV-B regions (where the wavelength of light is less than 425 nm) as compared to the imprinted film produced in Example 1b using an unpatterned polycarbonate film. This indicates that substrates comprising nano-sized surface features formed on a hierarchical array possess anti-UV effect.

Subsequent coating by ALD with TiO₂ as produced in Example 1c did not adversely affect the transmittance, only slightly reducing the transmittance to 93%, with the substrate comprising the hierarchical array with TiO₂ deposited thereon performing better than the substrate comprising the single array with TiO₂ deposited thereon.

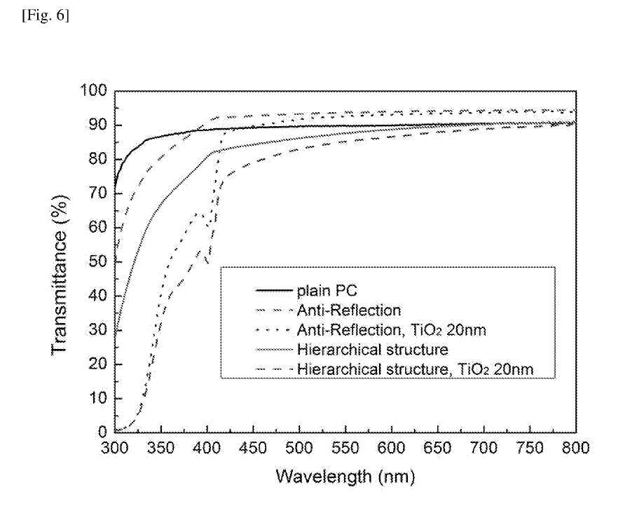

The above results are shown in the transmittance graph in FIG. 6. It can be seen from FIG. 6 that the graph for the TiO₂-coated textured polymer substrates drop sharply at wavelengths of about 425 nm and below. This indicates that there is a decrease in transmittance of wavelengths of 425 nm and below (i.e. a decrease in the transmittance of UV-A and UV-B wavelengths), evidencing an anti-UV effect of the coated substrates.

The light transmittance results of the imprinted films produced in Example 1 are shown in Table 2 as follows.

TABLE 2

| | Substrate | Substrate | |
|---|---|---|---|
| | comprising | comprising | |
| | hierarchical array | single array | Plain, non- |
| | with 20 nm TiO₂ | with 20 nm TiO₂ | patterned |
| | deposited thereon | deposited thereon | substrate |
| Visible light | 89.1% | 93.8% | 90.5% |
| transmittance | | | |
| UV transmittance | 50.4% | 60.1% | 88.6% |
| (at 400 nm) | | | |

The fog results of the imprinted films produced in Example 1 after a duration of time are shown in Table 3 as follows.

TABLE 3

| | Substrate comprising | Substrate comprising |
|---|---|---|
| | hierarchical array | single array |
| | with TiO₂ | with TiO₂ |
| | deposited thereon | deposited thereon |
| As fabricated | Clear | Clear |
| After 1 week | Very slightly fogging, fog | Slightly fogging, fog |
| | disappears quickly | disappears quickly |
| After 2 weeks | Slightly fogging, fog | Almost clear |
| | disappears quickly | |

It is therefore evidenced that both the single and hierarchical arrays maintain their anti-fogging properties.

### Example 5

In Example 5, cleaning of the imprinted and coated films produced from Example 1 is demonstrated. The cleaning treatment demonstrated here is a simple and effective way to activate and regenerate the ability of the anti-fog property of the surface of the imprinted films, which may be reduced with time due to contaminations such as oil and dust in the air.

The coated film was immersed in a cleaner solution for 2 minutes, rinsed with water and blow dried. The types of cleaner solution used in this example are shown below in Table 4.

TABLE 4

| Cleaner | Regeneration effect |
|---|---|
| Chlorine based bleach | Good |
| Ethanol | Poor |
| Isopropyl alcohol | Moderate |
| Oxygen based bleach | Good |

It can be seen that bleach produces desirable regeneration effects. However, chlorine based bleach produces an unpleasant smell and irritates the eyes and skin. Hence, oxygen based bleach is the best choice for cleaning of the disclosed coated and textured polymer substrate.

The fog results of the imprinted films produced in Example 1 with and without bleach treatment and after a duration of time are shown in Table 5 as follows.

TABLE 5

| | Substrate | | Substrate | |
|---|---|---|---|---|
| | comprising | | comprising | |
| | hierarchical array | | single array | |
| | with 20 nm TiO₂ | | with 20 nm TiO₂ | |
| | deposited thereon | | deposited thereon | |
| | No bleach | O₂ bleach | No bleach | O₂ bleach |
| | treatment | treatment | treatment | treatment |
| As fabricated | Very slightly | Clear | Very slightly | Clear |
| | fogging | | fogging | |
| After 1 week | Very slightly | Clear | Very slightly | Clear |
| | fogging | | fogging | |
| After 2 weeks | Slightly | Almost clear | Slightly | Almost clear |
| | fogging | | fogging | |
| After 5 weeks | Fogging | Very slightly | Slightly | Almost clear |
| | | fogging | fogging | |

It is therefore evidenced that the anti-fogging properties are improved when oxygen based bleach treatment is used as compared to when bleach treatment is not used.

### INDUSTRIAL APPLICABILITY

The disclosed method of preparing a polymer substrate may combine nanoimprinting technologies and deposition technologies to provide substrates having a combination of desirable properties. The disclosed method may be used for small-scale production or for large-scale production. The imprinting process may provide substrates having high clarity and reduced UV transmission. The deposition process may provide substrates having reduced UV transmission and anti-fogging properties.

The disclosed method may be performed directly on transparent equipment, such as swimming goggles, anti-UV eyewear and visors, to confer anti-fog and anti-UV properties. The disclosed textured polymer substrate may possess up to 94% visible light transmittance, while possessing less than 60% transmittance for wavelengths of less than 400 nm (i.e. the UV-A and UV-B regime). Accordingly, the disclosed textured polymer substrate may be used in applications where visible light transmittance is highly desired, but UV transmittance is not desired.

The disclosed textured polymer substrate may have relatively long-lasting surface hydrophilicity. Where the anti-fog ability degrades over time, the application further provides a method of reactivating and regenerating the anti-fog ability of the substrates.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1-25. (canceled)

26. A textured polymer substrate comprising nano-sized surface features which are integrally formed on at least one surface of the polymer substrate, said polymer substrate surface having at least one amorphous oxide layer deposited thereon, wherein said amorphous oxide layer comprises an oxide of a metal selected from titanium, cobalt, aluminum and composites thereof.

27. The textured polymer substrate of claim 26, wherein said nano-sized surface features are formed on a one-dimensional array or a single array or on a hierarchical array.

28. The textured polymer substrate of claim 26, wherein said polymer substrate surface comprises an array of micro-sized structures integrally formed on said polymer substrate, each micro-sized structure having at least one surface with nano-sized surface features imprinted thereon;
wherein the micro-sized structures are geometrically selected to be biomimetic.

29. The textured polymer substrate of claim 28, wherein said array of micro-sized structures comprises tessellated structures selected from the group consisting of: trigonal, tetragonal, square, rhombic, pentagonal, hexagonal, heptagonal, octagonal, nonagonal, decagonal, undecagonal, dodecagonal, tridecagonal and tetreadecagonal structures.

30. The textured polymer substrate of claim 29, wherein said array of micro-sized structures comprises ommatidium or ommatidia-like structures.

31. The textured polymer substrate of claim 28, wherein said micro-sized structures comprises at least one diameter dimension of between about 1 to about 15 microns.

32. The textured polymer substrate of claim 26, wherein at least a height dimension, or at least a width dimension, or both, of said nano-sized surface features is lesser than 390 to 700 nm.

33. The textured polymer substrate of claim 26, wherein said amorphous oxide layer has a substantially uniform thickness deposited by a chemical vapor deposition process, characterized in that said process is performed at a temperature below the glass transition temperature of said polymer substrate.

34. The textured polymer substrate of claim 26, wherein said amorphous oxide layer is deposited by Atomic Layer Deposition.

35. The textured polymer substrate of claim 26, wherein said polymer substrate is substantially optically transparent.

36. The textured polymer substrate of claim 26, wherein said amorphous oxide layer comprises amorphous titanium oxide.

37. A method of preparing a polymer substrate, said method comprising:
imprinting a surface of said polymer substrate with a patterned mold to integrally form a patterned surface having an array of micro-sized structures;
embossing said patterned surface to form a hierarchical array, wherein nano-sized surface features are integrally formed on a surface of said micro-sized structures; and
depositing an amorphous oxide layer over said polymer substrate surface, wherein said amorphous oxide layer comprises an oxide of a metal selected from titanium, cobalt, aluminum and composites thereof.

38. The method of claim 37, wherein said depositing comprises atomic layer deposition.

39. The method of claim 37, wherein said imprinting is performed at a temperature above the glass transition temperature of said polymer substrate.

40. The method of claim 37, wherein said embossing is performed at a temperature lower than the glass transition temperature of said polymer substrate.

41. The method of claim 37, wherein the mold of said imprinting is selected to provide tesallated polygonal structures on said patterned surface;
wherein said polygonal structures are micro-sized structures.

42. The method of claim 41, wherein said embossing comprises contacting at least a surface of said micro-sized polygonal structures with a second mold to integrally form a plurality of nano-sized surface features, thereby forming a hierarchical array.

43. The method of claim 42, wherein the nano-sized surface features comprises structures selected from the group consisting of: nano-cones, nano-pyramids, nano-cylinders, nano-needles, nano-blades, and combinations thereof.

44. The method of claim 37, wherein said amorphous oxide layer is amorphous titanium oxide.

45. The method of claim 44, wherein said deposition is undertaken to obtain a thickness of said amorphous titanium oxide layer of from about 10 to 50 nm.
